(19) United States
(12) Patent Application Publication
(10) Pub. No.: US 2004/0229430 A1
(43) Pub. Date: Nov. 18, 2004

(54) Fabrication process for a magnetic tunnel junction device

(76) Inventors: Frank Findeis, Hopewell Junction, NY (US); Ihar Kasko, Fishkill, NY (US); Wolfgang Raberg, Fishkill, NY (US)

Correspondence Address: SLATER & MATSIL, L.L.P., 17950 PRESTON RD, SUITE 1000, DALLAS, TX, 75252-5793, US

(21) Appl. No.: 10/437,772

(22) Filed: May 14, 2003

(51) Int. Cl. H01L 21/336

(52) U.S. Cl. 438/257

(57) ABSTRACT

A magnetic random access memory device having a magnetic tunnel junction is provided, as well as methods of fabricating the same. The magnetic tunnel junction includes a first magnetic layer, a second magnetic layer, a tunnel barrier layer, and dielectric material portions. The first magnetic layer is formed over the second magnetic layer. The tunnel barrier layer is located between the first and second magnetic layers. The dielectric material portions are formed on sidewalls of the first magnetic layer and over the second magnetic layer. The dielectric material portions may be formed directly atop the second magnetic layer. In another embodiment, the dielectric material portion may be formed directly atop the tunnel barrier layer. Preferably, the dielectric material portions prevent shorts from developing across the tunnel barrier layer during the etching of the second magnetic layer.

### FIELD OF THE INVENTION

The present invention relates generally to the fabrication of semiconductor devices, and more specifically to the fabrication of magnetic tunnel junction devices, such as magnetic random access memory (MRAM) devices.

### BACKGROUND

A recent development in memory devices involves spin electronics, which combines principles of semiconductor technology and magnetism. The electron spin, rather than the charge, may be used to indicate the presence of a “1” or “0” binary state in a magnetic tunnel junction device. One such spin electronics device is a magnetic random access memory (MRAM) device. FIG. 1 illustrates a simplified schematic for a portion of a typical MRAM device 20. In an MRAM device 20, conductive lines 22 (e.g., word lines and bit lines) are positioned perpendicular to each other in different metal layers. The conductive lines 22 sandwich a magnetic tunnel junction (MTJ) 30. Each MTJ 30 has at least two magnetic layers 31, 32 separated by a tunnel barrier layer 34 between them. The storage mechanism relies on the relative orientation of the magnetization of the two magnetic layers 31, 32, and the ability to discern or sense this orientation electrically through electrodes (i.e., the conductive lines 22) attached to these magnetic layers 31, 32. Hence, digital information represented as a “0” or “1” is storable in the relative alignment of magnetic moments in each MTJ 30. For general background regarding magnetic tunnel junction devices and MRAM devices, reference may be made to U.S. Pat. Nos. 6,538,919, 6,385,082, 5,650,958, and/or 5,640,343, for example. Each of these patents is incorporated herein by reference.

In a magnetic tunnel junction device 40, it is essential that the two magnetic layers 31, 32 in each MTJ 30 are isolated from each other by the tunnel barrier layer 34. Although shown as single layers for purposes of simplifying the illustration, the magnetic layers 31, 32 are typically each formed of multiple stacked layers of various materials. FIGS. 2 and 3 illustrate a typical process for forming a MTJ 30 for an magnetic tunnel junction device 40 (e.g., an MRAM device). FIG. 2 is a cross-section view showing two magnetic layers 31, 32 formed over a conducting line 22 (e.g., a word line or a bit line) with a tunnel barrier layer 34 sandwiched therebetween. A hard mask 42 is located atop the upper magnetic layer 31. At this stage, the hard mask 42 has already been patterned. Next in this conventional process, both magnetic layers 31, 32, along with the tunnel barrier layer 34, are patterned according to the hard mask 42 using wet etching, reactive ion etch (RIE), and/or ion milling, which are preferred for their ability to anisotropically etch in a controlled direction (e.g., to provide vertical sidewalls for the MTJ 30). FIG. 3 shows the MTJ 30 formed from such process. Note that a portion of the hard mask 42 may remain after this step, as shown in FIG. 3, and any remaining hard mask 42 may be later removed.

Although RIE and ion milling provide the advantage of anisotropic (directional) removal of material, the main drawback of RIE and ion milling is the discharge of displaced particles being removed during the process, which can be projected in many different directions. Hence, a major concern and problem with the above-described process of forming the MTJ 30 (FIGS. 2 and 3) is re-deposition of resputtered material from the magnetic layers 31, 32 and/or the underlying conductive line 22, which are electrically conductive materials, onto the MTJ 30 at the tunnel barrier layer 34. Such re-deposition may cause a short between the two magnetic layers 31, 32, which need to be electrically insulated from each other across the tunnel barrier layer 34 for the MTJ 30 to work properly. Thus, there is a need for a method to form the MTJ 30 while significantly decreasing or eliminating the risk that electrically conductive materials may be re-deposited onto the MTJ 30 causing a short.

### BRIEF SUMMARY OF THE INVENTION

The problems and needs outlined above are addressed by the present invention. In accordance with one aspect of the present invention, a method of fabricating a magnetic tunnel junction device is provided. The method includes the following steps, the order of which may vary. A patterned hard mask over a first magnetic layer is provided. The first magnetic layer is located over a tunnel barrier layer and a second magnetic layer. The tunnel barrier layer is located between the first and second magnetic layers. The first magnetic layer is etched in alignment with the patterned hard mask. A dielectric layer is formed over exposed portions of the etched first magnetic layer. The second magnetic layer is etched such that portions of the dielectric layer remain to cover the prior exposed portions of the first magnetic layer during the etching of the second magnetic layer. At least part of the tunnel barrier layer may be etched in alignment with the patterned hard mask, with the etching of the tunnel barrier layer stopping within the tunnel barrier layer, or after passing through the tunnel barrier layer, for example. The etching of the first magnetic layer and the etching of the tunnel barrier layer may occur during a same etching step. The etching of the first magnetic layer may occur until the tunnel barrier layer is reached and stops atop the tunnel barrier layer. The etching of the first magnetic layer may include wet etching, reactive ion etching, and/or ion milling. The dielectric layer may be anisotropically etched to expose part of the second magnetic layer. The etching of the dielectric layer and the etching of the second magnetic layer may occur during a same etching step. The etching of the second magnetic layer includes anisotropic etching, such as reactive ion etching and/or ion milling. The magnetic tunnel junction device may be a magnetic random access memory device, for example.

In accordance with another aspect of the present invention, a method of fabricating a magnetic tunnel junction device is provided. A patterned hard mask over a first magnetic layer is provided. The first magnetic layer is located over a tunnel barrier layer and a second magnetic layer. The tunnel barrier layer is located between the first and second magnetic layers. The first magnetic layer is patterned with a first etch in alignment with the patterned hard mask until the tunnel barrier layer is reached. The first etch uses an etch chemistry that is selective against etching the tunnel barrier layer. A dielectric layer is formed over exposed portions of the etched first magnetic layer. The tunnel barrier layer and the second magnetic layer are patterned with a second etch such that portions of the dielectric layer remain to cover the prior exposed portions of the first magnetic layer during the patterning of the second magnetic layer. The first etch may stop within or atop the tunnel barrier layer, for example. The first etch may include wet etching and/or reactive ion etching, for example. The second etch may include anisotropic etching, such as reactive ion etching and/or ion milling.

In accordance with still another aspect of the present invention, a method of fabricating a magnetic tunnel junction device is provided. In this method, a patterned hard mask over a first magnetic layer is provided. The first magnetic layer is located over a tunnel barrier layer and a second magnetic layer. The tunnel barrier layer is located between the first and second magnetic layers. The first magnetic layer and the tunnel barrier layer are patterned with a first etch in alignment with the patterned hard mask. A dielectric layer is deposited such that portions of the dielectric layer cover exposed sidewalls of the patterned first magnetic layer and sidewalls of the patterned tunnel barrier layer. The dielectric layer and the second magnetic layer are patterned with a second etch. The second etch is anisotropic so that at least part of the dielectric layer portions remain on the sidewalls of the patterned first magnetic layer and the sidewalls of the patterned tunnel barrier layer during the second etch.

In accordance with another aspect of the present invention, a magnetic random access memory device having a magnetic tunnel junction is provided. The magnetic tunnel junction includes a first magnetic layer, a second magnetic layer, a tunnel barrier layer, and a dielectric material portion. The first magnetic layer is formed over the second magnetic layer. The tunnel barrier layer is located between the first and second magnetic layers. The dielectric material portion is formed on a sidewall of the first magnetic layer and over the second magnetic layer. The dielectric material portion may be formed directly atop the second magnetic layer. In another embodiment, the dielectric material portion may be formed directly atop the tunnel barrier layer. Each magnetic layer may be a multi-layer structure including multiple layers of various materials.

In accordance with still another aspect of the present invention, a magnetic random access memory device is provided, which has a magnetic tunnel junction. The magnetic tunnel junction includes a first magnetic layer formed over a second magnetic layer. The first magnetic layer is electrically insulated from the second magnetic layer by a tunnel barrier layer located between the first and second magnetic layers and by a dielectric formed on a sidewall of the first magnetic layer before a majority of the second magnetic layer is patterned for the magnetic tunnel junction. The dielectric may be also formed over a sidewall of the tunnel barrier layer before the majority of the second magnetic layer is patterned for the magnetic tunnel junction.

### BRIEF DESCRIPTION OF THE DRAWINGS

Other objects and advantages of the invention will become apparent upon reading the following detailed description and upon referencing the accompanying drawings, in which:

FIG. 1 is a simplified schematic showing a portion of an MRAM device;

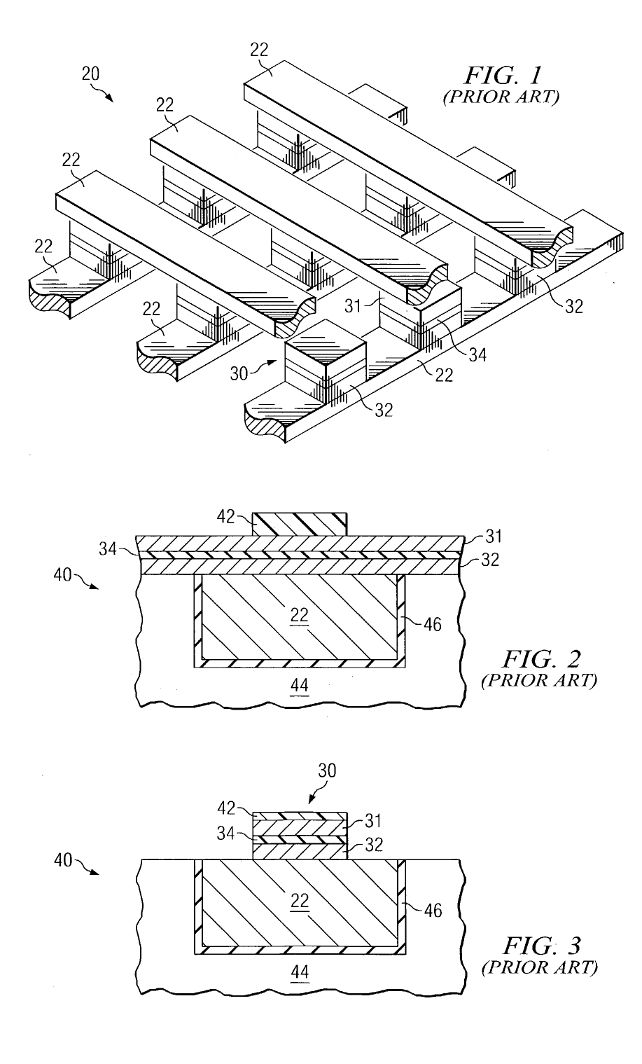

FIGS. 2 and 3 are cross-section views showing fabrication steps in a conventional process of forming a MTJ for an MRAM device;

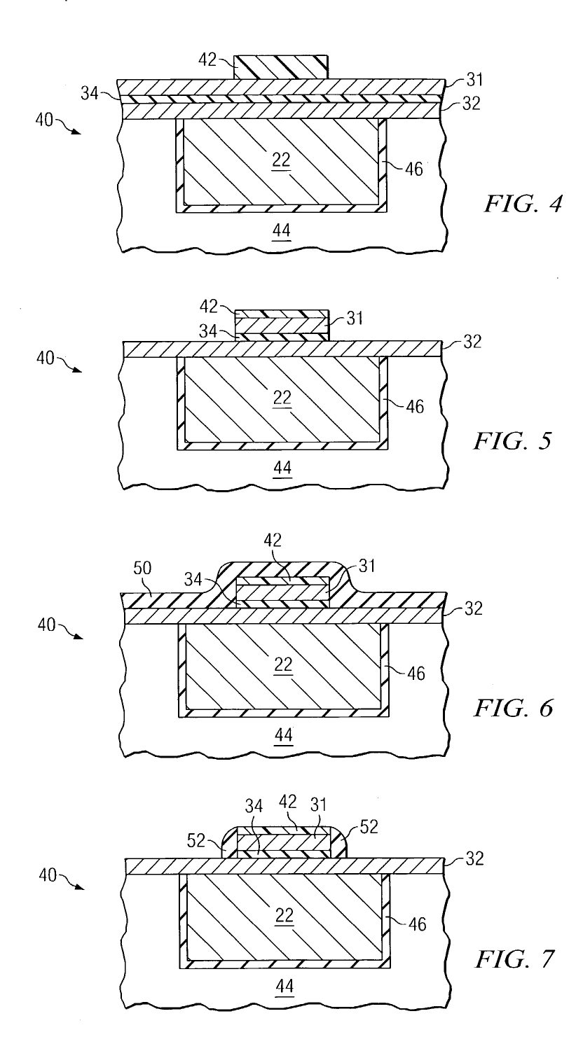

FIGS. 4-8 illustrate a preferred method of fabricating a MTJ for a magnetic tunnel junction device (e.g., an MRAM device) in accordance with a first embodiment of the present invention; and

FIGS. 9-13 illustrate another preferred method of fabricating a MTJ for a magnetic tunnel junction device in accordance with a second embodiment of the present invention.

### DETAILED DESCRIPTION OF PREFERRED EMBODIMENTS

Referring now to the drawings, wherein like reference numbers are used herein to designate like elements throughout the various views, preferred embodiments of the present invention are illustrated and described. The figures are not necessarily drawn to scale, and in some instances the drawings have been exaggerated and/or simplified in places, for illustrative purposes only. One of ordinary skill in the art will appreciate the many possible applications and variations of the present invention based on the following examples of possible embodiments of the present invention.

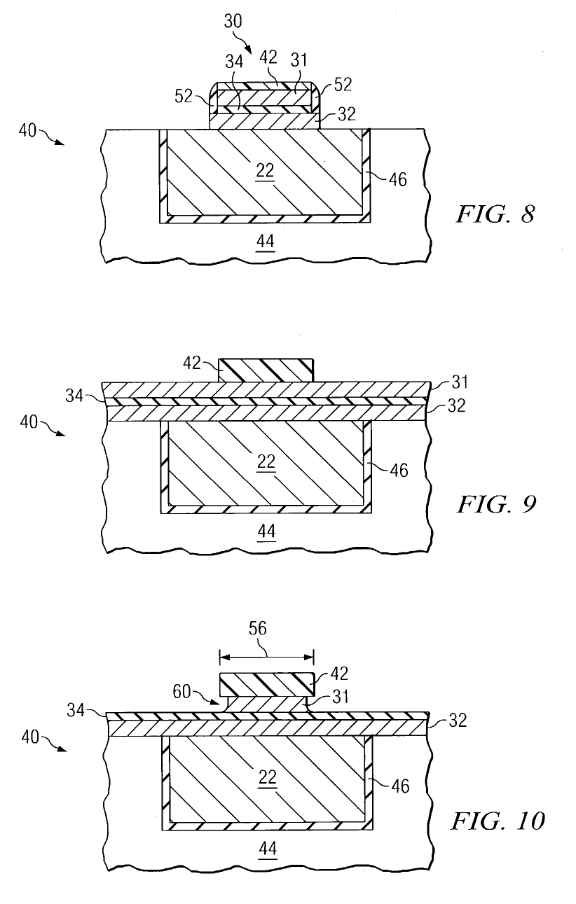

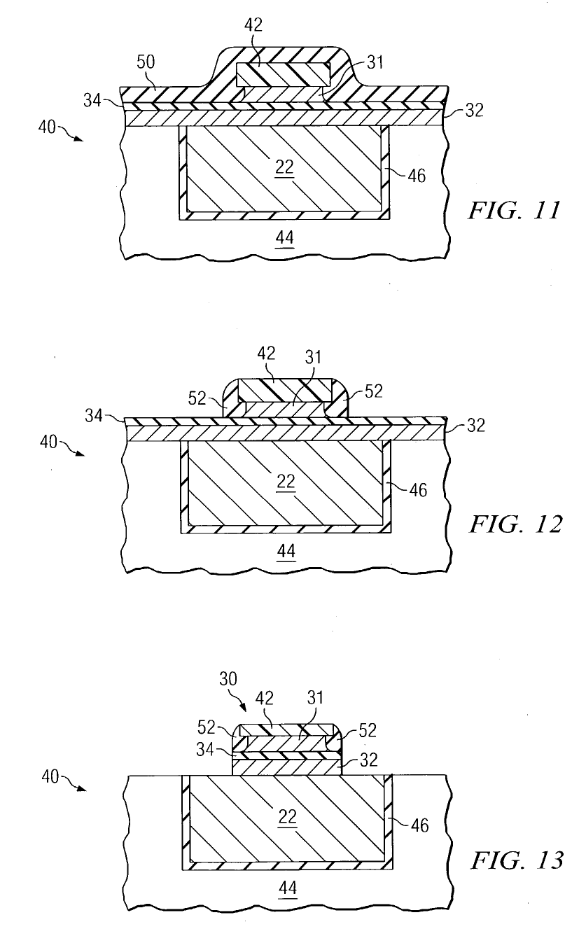

An embodiment of the present invention may provide a method to form a magnetic tunnel junction (MTJ) for an MRAM device while significantly decreasing or eliminating the risk that electrically conductive materials may be re-deposited onto the MTJ causing a short. FIGS. 4-8 illustrate a preferred method of fabricating a MTJ 30 for a magnetic tunnel junction device 40 (e.g., an MRAM device) in accordance with a first embodiment of the present invention. FIGS. 9-13 illustrate another preferred method of fabricating a MTJ 30 for a magnetic tunnel junction device 40 in accordance with a second embodiment of the present invention. These methods and their resulting structures will be described next.

Referring first to FIG. 4, two magnetic layers 31, 32 are formed atop a conducting line 22 (e.g., a word line or a bit line) with a tunnel barrier layer 34 sandwiched therebetween. The conducting line 22 may be formed in a substrate or some other layer (e.g., inter-metal dielectric, inter-level dielectric, insulating layer) 44, for example. The conducting line 22 may have a liner layer 46, which is typical. A hard mask 42 is located atop the upper magnetic layer 31. At this stage in FIG. 4, the hard mask 42 has already been patterned. The hard mask 42 may be patterned using known methods, for example.

The hard mask 42 may be made from a variety of materials, include but not limited to: titanium nitride, tantalum, tantalum nitride, silicon oxide, silicon nitride, aluminum oxide, silicon carbide (e.g. Blok™ by Applied Materials), or some combination, lamination, or composite thereof, for example. Preferably the hard mask 42 is made from some type of hard metal that can resist erosion from the etch processes needed to pattern the MTJ 30. A hard mask 42 may have a width of about 300 nm and a thickness of about 150 nm, for example. In a preferred embodiment, the hard mask is made from TiN, for example.

The magnetic layers 31, 32 may be made from a variety of materials, including but not limited to: nickel iron, cobalt iron, cobalt, amorphous cobalt-iron-boron alloy, ruthenium, platinum manganese, nickel platinum, iridium manganese, or some combination, lamination, or composite thereof, combinations thereof, and using various ratios of these chemical elements or compounds, for example. Each magnetic layer 31 or 32 may be formed of multiple stacked layers of materials. Each magnetic layer 31 or 32 in a MTJ 30 may differ from each other. Each magnetic layer 31 or 32 may have a thickness of about 10 nm, for example. In a preferred embodiment, for example, a “reference” magnetic layer includes multiple layers of materials such as PtMn, CoFe, Ru, and amorphous CoFeB alloy. Also in a preferred embodiment, a “free” magnetic layer includes multiple layers of materials, such as amorphous CoFeB alloy and NiFe, for example. The reference magnetic layer and the free magnetic layer may have the same multi-layer structure, or they may differ.

The tunnel barrier layer 34 may be made from a variety of material as well, including but not limited to: aluminum oxide, magnesium oxide, hafnium oxide, silicon oxide, silicon nitride, any dielectric material commonly used as a gate dielectric material, or some combination, lamination, or composite thereof, for example. The tunnel barrier layer 34 may have a thickness of about 1 nm, for example. In a preferred embodiment, for example, the insulated barrier layer 34 is made from aluminum oxide (Al₂O₃).

Next in the fabrication process shown in FIGS. 4-8, an etch is performed through the upper magnetic layer 31 and stopping at or in the tunnel barrier layer 34. However, because the tunnel barrier layer 34 is typically very thin (e.g., about 1 nm in thickness), it may be difficult to stop precisely at or in the tunnel barrier layer 34. Hence, the etch may go through the tunnel barrier layer 34 and slightly into the lower magnetic layer 32. The resulting structure is shown in FIG. 5. Any type of etch or combination of etches may be used for this first etch in the process, including wet etching, RIE, and/or ion milling, for example.

There are at least three techniques that may be used to control the stopping point of the first etch to obtain the intermediate structure shown in FIG. 5. One technique is to perform the etch for a specified and predetermined period of time. Another technique is to uses endpoint signal control based on feedback from sensors to stop at a predetermined layer. A third technique is to use an etch chemistry that is selective against etching the tunnel barrier layer 34. However, this third technique may not be possible for certain types of etches (e.g., ion milling). Also, any combination of these three techniques may be used to control the stopping point of an etch process. One of ordinary skill in the art may realize other techniques or ways that may be used to control the stopping point of this etch.

A dielectric layer 50 is then deposited over the structure of FIG. 5 to result in the structure shown in FIG. 6. The dielectric layer 50 is preferably applied relatively thick, as much of it will be eroded away during subsequent etching. Preferably, the dielectric layer 50 is applied in a conformal manner (e.g., CVD) so that it covers the exposed portions of the upper magnetic layer 31 (see FIGS. 5 and 6). If the tunnel barrier layer 34 has been etched through, as shown in FIG. 5, the dielectric layer 50 will preferably cover the exposed edges of the tunnel barrier layer 34 as well (see e.g., FIG. 6). In this process, it is important that the exposed portions of the upper magnetic layer 31 (see FIG. 5) are covered by the dielectric layer to protect it from redeposition of resputtered particles from the lower magnetic layer 32, as discussed below.

The dielectric layer 50 may be made from a variety of material, including but not limited to: aluminum oxide, silicon oxide, silicon nitride, silicon carbide (e.g. Blok™ by Applied Materials), or some combination, lamination, or composite thereof, for example. The dielectric layer 50 may be formed of a single layer of one material, multiple stacked layers of like materials, or multiple layers of different materials. The dielectric layer 50 may have a thickness of about 50 nm, for example. Preferably, the dielectric layer 50 is somewhat resistive against being etched by the etch (e.g., RIE) used to pattern the lower magnetic layer 32. In a preferred embodiment, for example, the dielectric layer 50 may be made from silicon oxide or silicon nitride.

The dielectric layer 50 is then etched with an anisotropic etch (e.g., RIE, ion milling). Preferably, most of the dielectric layer 50 is removed by the etching except for a vertically oriented portion of the dielectric layer 50 that covers the prior-exposed portions of the upper magnetic layer 31, as shown in FIG. 7. The same anisotropic etch may be continued, or another anisotropic etch may be begun, to etch the lower magnetic layer 32, as shown in FIG. 8. RIE or ion milling may be used for this portion of the process (i.e., FIGS. 7 and 8). Currently, RIE is preferred and has been found to work better than ion milling for this portion of the process.

Because the prior-exposed portions of the etched upper magnetic layer 31 are covered and shielded by the remaining portions 52 of the dielectric layer 50, redeposition of resputtered material discharged from the lower magnetic layer 32 is not a concern. In other words, any redeposited material from the resputtered lower magnetic layer 32 will not be able to form in a location that may cause a short between the upper and lower magnetic layers 31, 32 because the remaining portions 52 of the dielectric layer 50 cover and protect the sides of the upper magnetic layer 31 at and near the tunnel barrier layer 34. Thus, the functionality and reliability of the MTJ 30 can be maintained or improved from the possibility of shorts caused by redeposition during anisotropic etching of the lower magnetic layer 32. The remaining portion of the hard mask 42 (see FIG. 8) may be later removed, if needed.

Referring now to FIGS. 9-13, another preferred method of fabricating a MTJ 30 for a magnetic tunnel junction device 40 (e.g., an MRAM device) in accordance with a second embodiment of the present invention will be described. FIG. 9 is the same as FIG. 4, described above. Two magnetic layers 31, 32 are formed atop a conducting line 22 with a tunnel barrier layer 34 sandwiched therebetween. A patterned hard mask 42 is located atop the upper magnetic layer 31. For this method, a wet etch or a RIE is performed to pattern the upper magnetic layer 31 with an etch chemistry that is selective against etching the tunnel barrier layer 34. Hence, the etch is preferably stopped (or greatly slowed) when it reaches the tunnel barrier layer 34 (i.e., atop the tunnel barrier layer 34). The resulting structure after this etch is shown in FIG. 10.

If an isotropic wet etch is used, there will likely be some undercutting, as shown in FIG. 10 (by way of example). However, due to the dimensions of the upper magnetic layer 31 and the width 56 of the MTJ 30 being patterned, the undercutting should not be significant in most cases. For example, if the upper magnetic layer 31 has a thickness of about 10 nm and the hard mask 42 has a width of about 300 nm, the undercutting may only be about 3%, which is acceptable for most cases. Note that the undercutting shown in FIG. 10 is greatly exaggerated for purposes of illustration. A RIE would have much less or no undercutting, but may be less etch selective than the wet etch. Hence, there may be a trade off between having anisotropic etching with less or no undercutting and having high etch selectivity.

Next, a dielectric layer 50 is formed over the structure of FIG. 10. Preferably, the deposition of the dielectric layer 50 is conformal so that all exposed surfaces of the upper magnetic layer 31 shown in FIG. 10 are covered with by the dielectric layer 50, and preferably the dielectric layer 50 forms in the corners 60 where the upper dielectric layer 31 interfaces with the tunnel barrier layer 34 (see FIG. 10). The resulting structure after depositing the dielectric layer 50 is shown in FIG. 11.

An anisotropic etch is then performed to pattern the dielectric layer 50 and the lower magnetic layer 32, as shown in FIGS. 12 and 13. The dielectric layer 50 and the lower magnetic layer 32 may be etched used the same or different etches. This etch step may be a RIE or ion milling, for example. Because the etch is anisotropic, a vertical oriented portion of the dielectric layer 50 remains on the sidewalls (i.e., the prior exposed portions shown in FIG. 10) of the upper magnetic layer 31 during the etching of the lower magnetic layer 32 (see FIGS. 12 and 13). As a result, any redeposited conductive material resputtered from the lower magnetic layer 31 and/or the underlying conducting line 22 will not form a short between the upper magnetic layer 31 and the lower magnetic layer 32. In other words, the remaining portions 52 of the dielectric layer 50 shown in FIGS. 12 and 13 act as a barrier or shield to prevent redeposited electrically conductive material from bridging between the upper and lower magnetic layers 31, 32 around the tunnel barrier layer 34. The remaining portion of the hard mask 42 (see FIG. 13) may be later removed, if needed.

The illustrative embodiments shown in FIGS. 4-13 may be used for the formation of an MRAM device. With the benefit of this disclosure, one of ordinary skill in the art should realize that an embodiment of the present invention may be applied to the fabrication of many other types of MTJs (not shown) for other magnetic tunnel junction devices. For example, a MTJ for an MRAM device may have multiple layers making up a magnetic layer, and/or multiple layers making up a tunnel barrier layer. Also, in other embodiments (not shown), there may be other layers above and/or below the magnetic layers in the MTJ. Also, an embodiment of the present invention may be incorporated in many types of magnetic tunnel junction devices.

During a process of the present invention, such as the first and second embodiments described above (see FIGS. 4-13), the etching of the lower magnetic layer 32 may etch away the dielectric layer 50 more quickly than desired. For example, if a RIE process is used to etch and pattern the lower magnetic layer 32 and the etch selectivity of the RIE with respect to the dielectric layer 50 is not high enough, the dielectric layer 50 may be etched away at the sidewall of the upper magnetic layer 31 before the etching of the lower magnetic layer 32 is complete. Hence, for some scenarios, it may be desirable or necessary to interrupt the etching of the lower magnetic layer 32 and deposit another dielectric layer (e.g., just as dielectric layer 50 was deposited, as shown in FIGS. 6 and 11) to maintain protection of the upper magnetic layer's sidewalls. Such deposition of another dielectric layer is preferably a conformal deposition process to ensure that the vertically oriented portions of the intermediate structure are sufficiently covered and protected. Also, such deposition of another dielectric layer is preferably performed before the prior dielectric layer 50 is completely etched away and/or before any portion of the upper magnetic layer 31 becomes exposed. However, in other embodiments, the deposition of another dielectric layer may be performed after a portion of the upper magnetic layer 31 becomes exposed and/or after the prior dielectric layer 50 is mostly or completely etched away. Also, this process of redepositing another dielectric layer during the etching of the lower magnetic layer 32 (or any other layer(s), e.g., etching a conducting line 22) may be repeated as many times as desired or needed to maintain protection or coverage of the upper dielectric layer 31.

It will be appreciated by those skilled in the art having the benefit of this disclosure that this invention provides improved structures for use in magnetic tunnel junction devices and methods of fabricating the same. It should be understood that the drawings and detailed description herein are to be regarded in an illustrative rather than a restrictive manner, and are not intended to limit the invention to the particular forms and examples disclosed. On the contrary, the invention includes any further modifications, changes, rearrangements, substitutions, alternatives, design choices, and embodiments apparent to those of ordinary skill in the art, without departing from the spirit and scope of this invention, as defined by the following claims. Thus, it is intended that the following claims be interpreted to embrace all such further modifications, changes, rearrangements, substitutions, alternatives, design choices, and embodiments.

What is claimed is:

1. A method of fabricating a magnetic tunnel junction device, comprising:
providing a patterned hard mask over a first magnetic layer, wherein the first magnetic layer is located over a tunnel barrier layer and a second magnetic layer, and wherein the tunnel barrier layer is located between the first and second magnetic layers;
etching the first magnetic layer in alignment with the patterned hard mask;
forming a dielectric layer over exposed portions of the etched first magnetic layer; and
etching the second magnetic layer such that portions of the dielectric layer remain to cover the prior exposed portions of the first magnetic layer during the etching of the second magnetic layer.

2. The method of claim 1, further comprising:
etching at least part of the tunnel barrier layer in alignment with the patterned hard mask.

3. The method of claim 2, wherein the etching of the tunnel barrier layer stops within the tunnel barrier layer.

4. The method of claim 2, wherein the etching of the tunnel barrier layer stops after passing through the tunnel barrier layer.

5. The method of claim 2, wherein the etching of the first magnetic layer and the etching of the tunnel barrier layer occur during a same etching step.

6. The method of claim 1, wherein the etching of the first magnetic layer occurs until the tunnel barrier layer is reached and stops atop the tunnel barrier layer.

7. The method of claim 1, wherein the etching of the first magnetic layer includes wet etching.

8. The method of claim 1, wherein the etching of the first magnetic layer includes reactive ion etching.

9. The method of claim 1, wherein the etching of the first magnetic layer includes ion milling.

10. The method of claim 1, further comprising:
anisotropically etching the dielectric layer to expose part of the second magnetic layer.

11. The method of claim 10, wherein the etching of the dielectric layer and the etching of the second magnetic layer occur during a same etching step.

12. The method of claim 1, wherein the etching of the second magnetic layer includes anisotropic etching.

13. The method of claim 12, wherein the anisotropic etching includes reactive ion etching.

14. The method of claim 12, wherein the anisotropic etching includes ion milling.

15. The method of claim 1, further comprising:
interrupting the etching of the second magnetic layer;
depositing another dielectric layer over an intermediate structure existing when the etching of the second magnetic layer is interrupted; and
continuing the etching of the second magnetic layer.

16. The method of claim 1, wherein the magnetic tunnel junction device is a magnetic random access memory device.

17. A method of fabricating a magnetic tunnel junction device, comprising:
providing a patterned hard mask over a first magnetic layer, wherein the first magnetic layer is located over a tunnel barrier layer and a second magnetic layer, and wherein the tunnel barrier layer is located between the first and second magnetic layers;
patterning the first magnetic layer with a first etch in alignment with the patterned hard mask until the tunnel barrier layer is reached, wherein the first etch uses an etch chemistry that is substantially selective against etching the tunnel barrier layer;
forming a dielectric layer over exposed portions of the etched first magnetic layer; and
patterning the tunnel barrier layer and the second magnetic layer with a second etch such that portions of the dielectric layer remain to cover the prior exposed portions of the first magnetic layer during the patterning of the second magnetic layer.

18. The method of claim 17, wherein the first etch stops within the tunnel barrier layer.

19. The method of claim 17, wherein the first etch stops atop the tunnel barrier layer.

20. The method of claim 17, wherein the first etch includes wet etching.

21. The method of claim 17, wherein the first etch includes reactive ion etching.

22. The method of claim 17, wherein the second etch includes anisotropic etching.

23. The method of claim 22, wherein the anisotropic etching includes reactive ion etching.

24. The method of claim 22, wherein the anisotropic etching includes ion milling.

25. A method of fabricating a magnetic tunnel junction device, comprising:
providing a patterned hard mask over a first magnetic layer, wherein the first magnetic layer is located over a tunnel barrier layer and a second magnetic layer, and wherein the tunnel barrier layer is located between the first and second magnetic layers;
patterning the first magnetic layer and the tunnel barrier layer with a first etch in alignment with the patterned hard mask;
depositing a dielectric layer such that portions of the dielectric layer cover exposed sidewalls of the patterned first magnetic layer and sidewalls of the patterned tunnel barrier layer; and
patterning the dielectric layer and the second magnetic layer with a second etch, wherein the second etch is anisotropic so that at least part of the dielectric layer portions remain on the sidewalls of the patterned first magnetic layer and the sidewalls of the patterned tunnel barrier layer during the second etch.

26. A magnetic random access memory device comprising a magnetic tunnel junction, the magnetic tunnel junction comprising:
a first magnetic layer;
a second magnetic layer, wherein the first magnetic layer is formed over the second magnetic layer;
a tunnel barrier layer located between the first and second magnetic layers; and
a dielectric material portion formed on a sidewall of the first magnetic layer and over the second magnetic layer.

27. The magnetic random access memory device of claim 26, wherein the dielectric material portion is formed directly atop the second magnetic layer.

28. The magnetic random access memory device of claim 26, wherein the dielectric material portion is formed directly atop the tunnel barrier layer.

29. The magnetic random access memory device of claim 26, wherein the first magnetic layer is a multi-layer structure including layers of materials selected from a group consisting of nickel iron, cobalt iron, cobalt, amorphous cobalt-iron-boron alloy, ruthenium, platinum manganese, nickel platinum, and iridium manganese.

30. The magnetic random access memory device of claim 26, wherein the second magnetic layer is a multi-layer structure including layers of materials selected from a group consisting of nickel iron, cobalt iron, cobalt, amorphous cobalt-iron-boron alloy, ruthenium, platinum manganese, nickel platinum, and iridium manganese.

31. The magnetic random access memory device of claim 26, wherein the tunnel barrier layer is made of a material selected from a group consisting of aluminum oxide, magnesium oxide, hafnium oxide, silicon oxide, and silicon nitride.

32. The magnetic random access memory device of claim 26, wherein the dielectric material portion is made of a material selected from a group consisting of aluminum oxide, silicon oxide, silicon nitride, and silicon carbide.

33. A magnetic random access memory device, comprising:
a magnetic tunnel junction including a first magnetic layer formed over a second magnetic layer, wherein the first magnetic layer is electrically insulated from the second magnetic layer by a tunnel barrier layer located between the first and second magnetic layers and by a dielectric formed on a sidewall of the first magnetic layer before a majority of the second magnetic layer is patterned for the magnetic tunnel junction.

34. The magnetic random access memory device of claim 33, wherein the dielectric is also formed over a sidewall of the tunnel barrier layer before the majority of the second magnetic layer is patterned for the magnetic tunnel junction.
